(19) United States
(12) Patent Application Publication
(10) Pub. No.: US 2008/0006950 A1
(43) Pub. Date: Jan. 10, 2008

(54) BONDING PAD STRUCTURE FOR ELECTRONIC DEVICE

(75) Inventors: Hsiao-Chu Lin, Taipei (TW); Sheng-Yuan Lee, Taipei (TW)

Correspondence Address: THOMAS, KAYDEN, HORSTEMEYER & RISLEY, LLP, 600 GALLERIA PARKWAY, STE 1500, ATLANTA, GA, 30339, US

(73) Assignee: VIA TECHNOLOGIES, INC., Taipei (TW)

(21) Appl. No.: 11/610,668

(22) Filed: Dec. 14, 2006

(30) Foreign Application Priority Data
Jul. 7, 2006 (TW) 95124786

(51) Int. Cl. H01L 23/52

(52) U.S. Cl. 257/784

(57) ABSTRACT

A pad structure for an electronic device is disclosed. The pad structure comprises an insulating layer, an uppermost metal layer and a metal layer. The insulating layer is disposed on a substrate. The uppermost metal layer is disposed on the insulating layer. The metal layer is disposed in the insulating layer under the uppermost metal layer and electrically connected to the uppermost metal layer by at least one conductive plug through the insulating layer. The metal layer has the same profile, but is smaller than, the uppermost metal layer.

### BACKGROUND OF THE INVENTION

1. Field of the Invention

The invention relates to integrated circuit fabrication, and more particularly to a bonding pad structure design capable of reducing parasitic capacitance.

2. Description of the Related Art

With continued development of semiconductor technologies, device size is continuously reduced to increase the integration of integrated circuits. Due to reductions in feature size, many formerly minor technical problems become prominent. For example, the connection between a bonding pad and a bonding wire can seriously affect the device reliability.

FIG. 1 illustrates a conventional bonding pad. A metal pad 14 is formed on an insulating layer 12 and electrically connected to the underlying substrate 10 or the device (not shown) on the substrate 10 through the conductive plugs (not shown) formed in the insulating layer 12. Typically, the insulating layer 12 comprises low k materials which can reduce resistance-capacitance (RC) delay caused by the insulating layer 12 and the metal layer and interconnect formed therein. When a bonding wire 16 is attached to the bonding pad 14, however, the bonding pad 14 must support larger stress. Low k materials with poor mechanical strength may thus cause the binding pad 14 peel off the insulating layer 12.

To solve the mentioned problems, a multi-layer bond pad, as shown in FIG. 2, has been suggested. The multi-layer bond pad comprises an uppermost metal layer 28 on an insulating layer 22, metal stack layers 24 and 26 formed in the insulating layer 22 and conductive plugs 23 for connecting the metal layers 24, 26 and 28. The metal stack layers 24 and 26 and the uppermost metal layer 28 have the same profile and plane size. The multi-layer bond pad is also electrically connected to an underlying substrate 20 or devices (not shown) on the substrate 20 through conductive plugs (not shown) formed in the insulating layer 22. Because the multi-layer bond pad can support greater stress than the single bonding pad, the uppermost metal layer 28 is less likely to peel off the insulating layer 22 when a bond wire 30 is attached to the multi-layer bond pad structure with. The distance between the multi-layer bond pad and the substrate 20 is, however, shorter than that between the single bonding pad and the substrate. Thus, a larger parasitic capacitance caused by the multi-layer bond pad and the substrate 20 results, such that the performance of high speed and high frequency integrated circuits is reduced.

To solve the mentioned problems, an improved bond pad structure design capable of reducing the parasitic capacitance while maintaining structural strength.

### BRIEF SUMMARY OF INVENTION

A detailed description is given in the following embodiments with reference to the accompanying drawings. Pad structures for an electronic device, an integrated circuit, and a chip are provided. An embodiment of a pad structure for an electronic device comprises an insulating layer, an uppermost metal layer, and a metal layer. The insulating layer is disposed on a substrate. The uppermost metal layer is disposed on the insulating layer. The metal layer is disposed in the insulating layer under the uppermost metal layer and electrically connected to the uppermost metal layer by at least one conductive plug through the insulating layer. The metal layer has the same profile as the uppermost metal layer does, but the size of the metal layer is smaller than that of the uppermost metal layer.

An embodiment of a pad structure for an integrated circuit comprises an insulating layer, an uppermost metal layer, and a metal layer. The insulating layer is disposed on a substrate. The uppermost metal layer is disposed on the insulating layer. The metal layer is disposed in the insulating layer under the uppermost metal layer and electrically connected to the uppermost metal layer by at least one conductive plug through the insulating layer. The metal layer and the uppermost metal layer have the same profile, but the size of the metal layer is smaller than that of the uppermost metal layer.

An embodiment of a pad structure for a chip comprises a plurality of metal layers and a plurality of layers with conductive plugs respectively disposed between the adjacent metal layers. At least one of the metal layers has a relatively larger area than others do.

### BRIEF DESCRIPTION OF DRAWINGS

The invention can be more fully understood by reading the subsequent detailed description and examples with references made to the accompanying drawings, wherein:

FIG. 1 is a cross-section of a conventional bonding pad;

FIG. 2 is a cross-section of another conventional bonding pad;

FIG. 3A is a plan view of an embodiment of a bonding pad for an electronic device;

FIG. 3B is a cross-section along 3B-3B line shown in FIG. 3A; and

FIG. 4 is a plan view of another embodiment of a bonding pad for an electronic device.

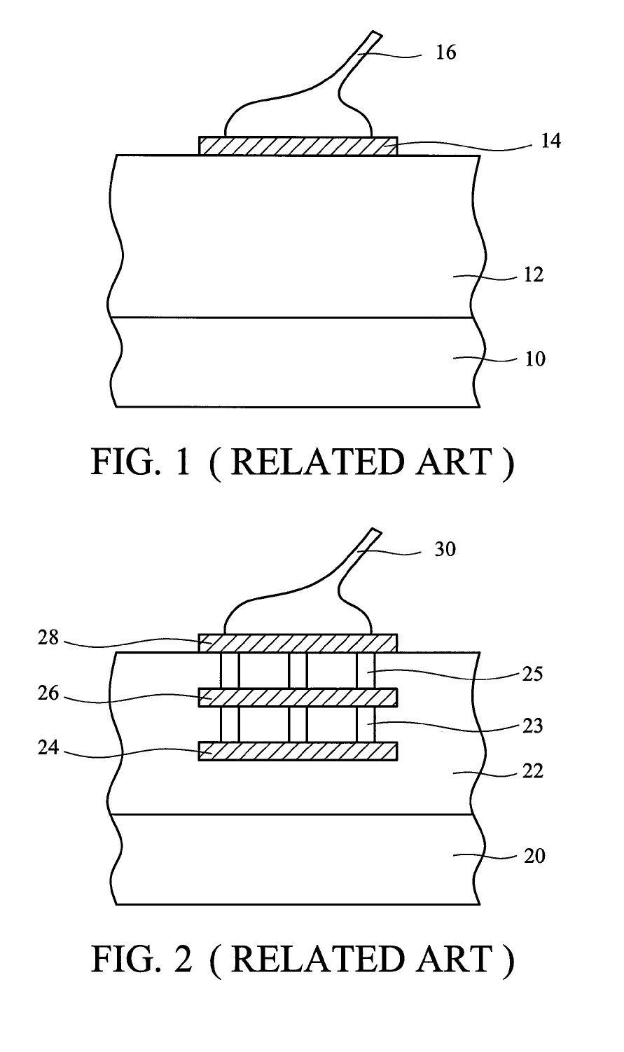

### DETAILED DESCRIPTION OF INVENTION

The following description is of the best-contemplated mode of carrying out the invention. This description is provided for the purpose of illustrating the general principles of the invention and should not be taken in a limiting sense. The scope of the invention is best determined by reference to the appended claims. The multi-layer bonding pad of the invention will be described in the following with reference to the accompanying drawings.

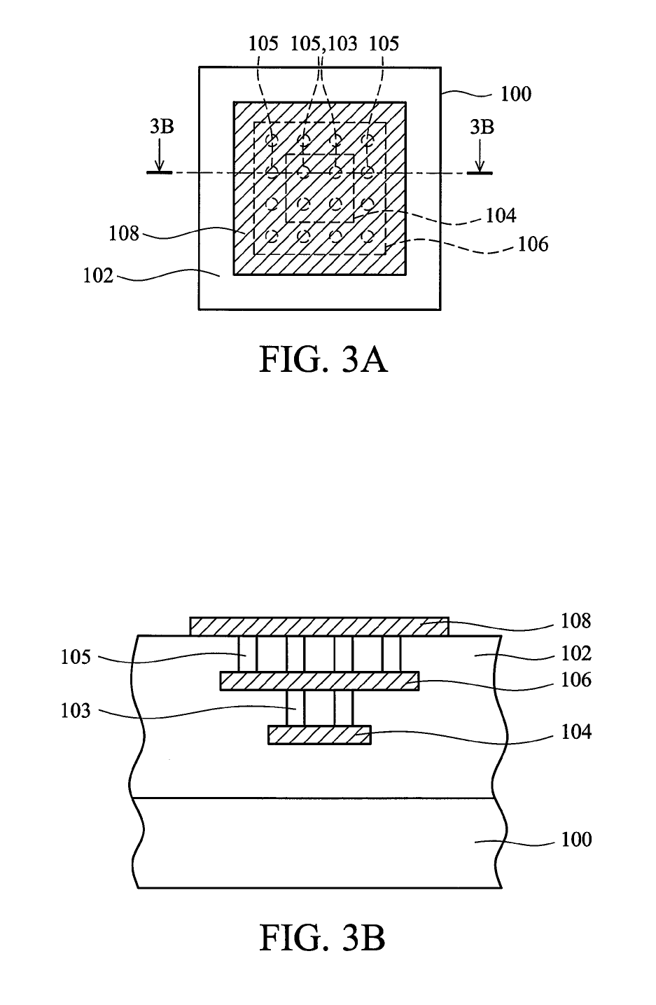

FIG. 3A is a plan view of an embodiment of a bonding pad for an electronic device. FIG. 3B is a cross-section along line 3B-3B. As shown in FIG. 3B, the bonding pad structure comprises an insulating layer 102, an uppermost metal layer 108, and metal layers 106 and 104. The insulating layer 102 is disposed on a substrate 100. The substrate 100 may be a silicon substrate or other semiconductor substrate. The substrate 100 may include various devices, such as transistors, resistors, or other well known semiconductor devices. Moreover, the substrate 100 may also include other insulating layers, such as inter-layer dielectric (ILD) layers or inter-metal dielectric (IMD) layers. To simplify the diagram, only a flat substrate is depicted.

In this embodiment, the insulating layer 102 may comprise at least one ILD or IMD layer. In the other words, the insulating layer 102 may be composed of a single insulating layer or multiple insulating layers.

Note that the insulating layer typically comprises a low k material, such as fluorinated silicate glass (FSG) or organo-silicate glass (OSG), for providing a lower RC (resistance-capacitance) time constant.

The uppermost metal layer 108, such as a cooper, aluminum, or alloy layer, is disposed on the insulating layer 102. The metal layer 106, such as a cooper, aluminum, or alloy layer, is disposed in the insulating layer 102 thereunder. At least one conductive plug 105 may be disposed in the insulating layer 102 between the metal layer 106 and the uppermost metal layer 108 to electrically connect the metal layer 106 and the uppermost metal layer 108 and to serve as a supporter for the uppermost metal layer 108.

In this embodiment, the metal layer 106 has the same profile as the uppermost metal layer 108 does, but it 106 has a smaller planar area than the uppermost metal layer 108 does, as shown in FIG. 3A. Note that when the difference between the size of the planar area of uppermost metal layer 108 and the metal layer 106 must be considered during design, due to structural strength requirements of the bonding pad. The profiles of the uppermost metal layer 108 and the metal layer 106 may be rectangular, pentagonal, hexagonal, or polygonal. Moreover, the area of the uppermost metal layer 108 is about 1.8 to 4 times that of the metal layer 106. Compared to the conventional multi-layer bonding pad having the same metal layer area, the area of the lower metal layer 106 is smaller than that of the uppermost metal layer 108, and thus the parasitic capacitance between the bonding pad and the substrate 100 can be reduced.

Additionally, the metal layer 104, such as a copper, aluminum, or alloy layer, may be optionally disposed in the insulating layer 102 under the metal layer 106. At least one conductive plug 103 may be disposed in the insulating layer 102 between the metal layers 104 and 106 to thus electrically connect the metal layers 104 and 106 and to serve as a supporter for the uppermost metal layer 108 and the metal layer 106. The conductive plug 105 may or may not be substantially aligned to the underlying conductive plug 103.

Note that an insulating layer comprising conductive plug(s) may be referred to as a conductive plug layer. The conductive plug layer comprises an insulating material for serving as an insulator between the conductive plugs.

In this embodiment, the metal layer 104 has the same profile as the metal layer 106 does, but it 104 has a smaller planar area than the metal layer 106 does. Thus, an inverted trapezoid multi-layer bonding pad structure, as shown in FIG. 3B, is formed. When the difference in the planar areas of the metal layers 104 and 106 is designed, the structural strength of the bonding pad must be considered. For example, the area of the metal layer 106 is about 1.8 to 4 times that of the metal layer 104. As a result, the parasitic capacitance between the bonding pad and the substrate 100 can be further reduced.

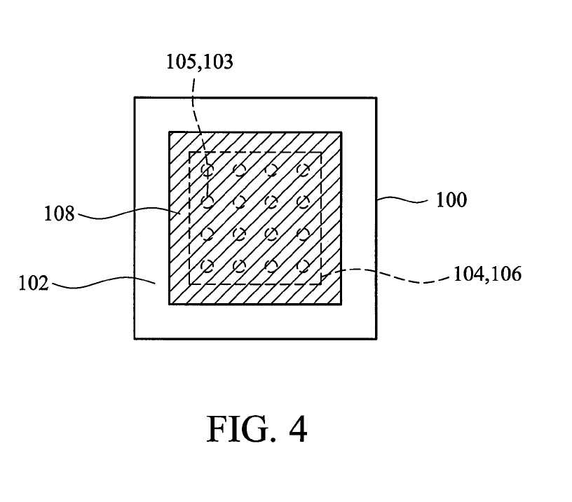

In some embodiments, the metal layer 104 has the same profile and planar area as the metal layer 106 does, as shown in FIG. 4. That is, the area of the uppermost metal layer 108 is about 1.8 to 4 times those of the metal layers 104 and 106.

That is, the design rule of the planar area of the metal layers is as follows: (1) the uppermost metal layer has the largest area (i.e. planar area); and (2) the area of the upper metal layer is about 1.8 to 4 times that of the lower metal layer.

When the bonding pad structure comprises more than three metal layers, the uppermost metal layer still has the largest area and the area of at least one of the underlying metal layers is about 1.8 to 4 times that of another underlying metal layer.

Compared to the conventional single bonding pad, the reversed trapezoid multi-layer bonding pad structure of the invention has a better structural strength, which can prevent the uppermost metal layer 108 from peeling off the insulating layer 102 during wire bonding, thereby increasing device reliability. Moreover, compared to the conventional multi-layer bonding pad structure having the same metal layer plane area and profile, the inverted trapezoid multi-layer bonding pad structure of the invention may provide relatively lower parasitic capacitance, thereby increasing the performance of the high speed and frequency integrated circuits.

Note that the electronic device may comprise an integrated circuit formed on a semiconductor wafer. The integrated circuit may comprise one or more electronic elements, such as CMOS transistors, diodes, resistors, or capacitors. In the other words, the bonding pad structure of the invention can be used in a semiconductor chip.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A pad structure for an electronic device, comprising:
a substrate;
an insulating layer disposed on the substrate;
an uppermost metal layer disposed on the insulating layer; and
a first metal layer disposed under the uppermost metal layer and electrically connected to the uppermost metal layer by at least one first conductive plug through the insulating layer;
wherein the first metal layer and the uppermost metal layer have the same profile, and the size of the first metal layer is smaller than that of the uppermost metal layer.

2. The pad structure as claimed in claim 1, wherein the area the uppermost metal layer is about 1.8 to 4 times that of the first metal layer.

3. The pad structure as claimed in claim 1, further comprising a second metal layer disposed under the first metal layer and electrically connected to the first metal layer by at least one second conductive plug; wherein the second metal layer and the first metal layer have the same profile, and the area of the second metal layer is smaller than that of the first metal layer.

4. The pad structure as claimed in claim 3, wherein the area of the uppermost metal layer is about 1.8 to 4 times that of the first metal layer, and the area of the first metal layer is about 1.8 to 4 times that of the second metal layer.

5. The pad structure as claimed in claim 1, further comprising a second metal layer disposed under the first metal layer and electrically connected to the first metal layer by at least one second conductive plug, wherein the second metal layer and the first metal layer have the same profile and size.

6. The pad structure as claimed in claim 5, wherein the area of the uppermost metal layer is about 1.8 to 4 times that of the first metal layer.

7. A pad structure for an integrated circuit, comprising:
an insulating layer;
an uppermost metal layer disposed on the insulating layer; and
a first metal layer disposed under the uppermost metal layer and electrically connected to the uppermost metal layer by at least one first conductive plug;
wherein the first metal layer and the uppermost metal layer have the same profile, and the size of the first metal layer is smaller than that of the uppermost metal layer.

8. The pad structure as claimed in claim 7, wherein the area of the uppermost metal layer is about 1.8 to 4 times that of the first metal layer.

9. The pad structure as claimed in claim 7, further comprising a second metal layer disposed under the first metal layer and electrically connected to the first metal layer by at least one second conductive plug, wherein the second metal layer and the first metal layer have the same profile, and the size of the second metal layer is smaller than that of the first metal layer.

10. The pad structure as claimed in claim 9, wherein the area of the uppermost metal layer is about 1.8 to 4 times that of the first metal layer, and the area of the first metal layer is about 1.8 to 4 times that of the second metal layer.

11. The pad structure as claimed in claim 7, further comprising a second metal layer disposed under the first metal layer and electrically connected to the first metal layer by at least one second conductive plug, wherein the second metal layer and the first metal layer have the same profile and size.

12. The pad structure as claimed in claim 11, wherein the area of the uppermost metal layer is about 1.8 to 4 times that of the first metal layer.

13. A pad structure for a chip, comprising:
a plurality of metal layers; and
a plurality of conductive plug layers disposed between the adjacent metal layers;
wherein the area of at least one the metal layer is larger than that of another one metal layer.

14. The pad structure as claimed in claim 13, wherein the uppermost metal layer has a surface exposed from the chip.

15. The pad structure as claimed in claim 13, wherein the conductive plug layer comprises an insulating material.

16. The pad structure as claimed in claim 15, wherein the insulating material is a low k material.

17. The pad structure as claimed in claim 13, wherein the conductive plug layer has at least one conductive plug.

18. The pad structure as claimed in claim 13, wherein the areas of the metal layers are decreased gradually from the uppermost metal layer to the lowest one.

19. The pad structure as claimed in claim 13, wherein the area of the upper one of two adjacent metal layers is about 1.8 to 4 times the area of the lower one of two adjacent metal layers.

20. The pad structure as claimed in claim 13, wherein the area of the uppermost metal layer is larger than those of other metal layers.
